(19) United States
(12) Patent Application Publication
(10) Pub. No.: US 2009/0087949 A1
(43) Pub. Date: Apr. 2, 2009

(54) Method of Making a Microelectronic Package Using an IHS Stiffener

(76) Inventor: Daoqiang Lu, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/864,267

(22) Filed: Sep. 28, 2007

(51) Int. Cl. H01L 21/00

(52) U.S. Cl. 438/111; 257/E23.001

(57) ABSTRACT

A method of making a microelectronic package. The method includes: providing a carrier; providing a tacky pad on the carrier; placing a die onto the tacky pad such that an active surface of the die adheres to the tacky pad, bonding an IHS onto a backside of the die after placing to form a die-IHS combination, removing the die-IHS combination from the tacky pad; and mounting the die-IHS combination onto a package substrate to form the package.

### FIELD

The present invention relates to methods of fabricating microelectronic packages, and especially to methods of fabricating microelectronic packages having ultra-thin dies.

### BACKGROUND

As microelectronic components shrink in size, a trend has emerged to provide microelectronic packages incorporating ultra-thin dies (that is, dies that have a thickness less than about 100 microns). The use of ultra-thin dies is beneficial to high-density integration, such as for an improvement in thermal performances and is further beneficial to a form factor reduction of the overall package.

Disadvantageously, ultra-thin dies have proven to be prone to mechanical failure, such as cracking or breaking, during packaging, and especially while they are being mounted onto a package substrate. Such dies are also typically difficult to handle. As a result, an additional issue affecting packaging using ultra-thin dies has been the lack of adequate placement accuracy of the die onto the package substrate. In addition, ultra-thin dies generally tend to exhibit significant warpage, especially in a temperature range associated with a bonding temperature of dies to substrates. Such warpage may disadvantageously cause low die to substrate assembly yield in a high volume manufacturing environment. In addition, even after an ultra-thin die is assembled onto a substrate, it still tends to exhibit significant warpage, as a result of which the thermal interface material between the die and the associated IHS (integrated heat spreader) has to be thick enough to accommodate the warpage. A thick TIM however, compromises the thermal performance of the package as a whole.

The prior art fails to provide a packaging method that ensures high assembly yield and good package reliability for microelectronic packages including ultra-thin dies.

### BRIEF DESCRIPTION OF THE DRAWINGS

FIGS. 1-6 show stages in the making of a microelectronic package according to an embodiment, and

FIG. 7 shows a side cross sectional view of a microelectronic package formed according to a method embodiment.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method of making a microelectronic package is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention,

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

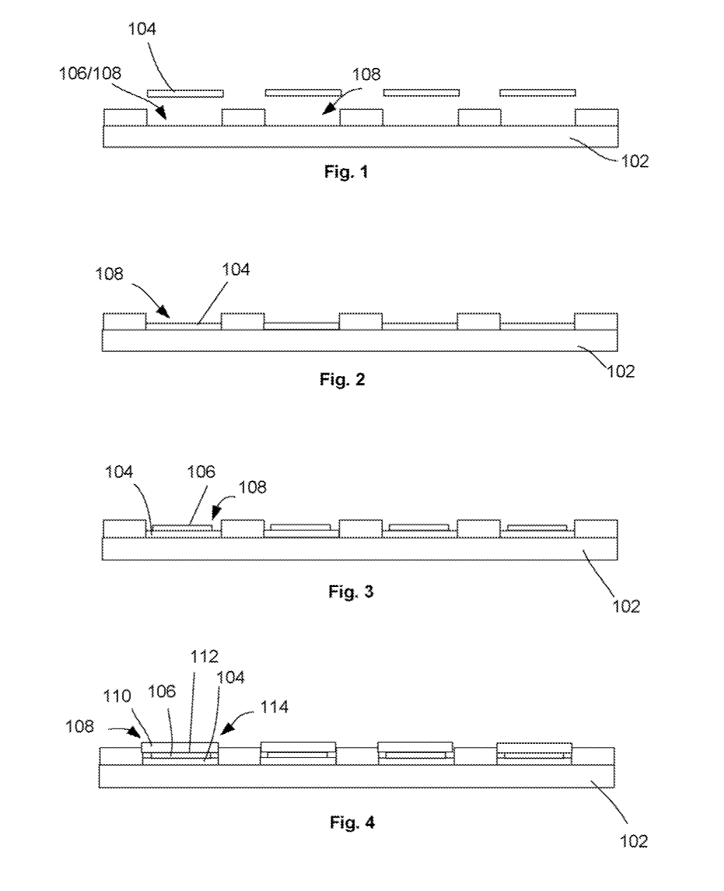

Aspects of this and other embodiments will be discussed herein with respect to FIGS. 1-7 below. The figures, however, should not be taken to be limiting, as it is intended for the purpose of explanation and understanding. The figures will be discussed in further detail below,

Referring first to FIGS. 1 and 2 by way of example, a method embodiment may include providing a carrier, such as carrier 102, and providing a tacky layer on the carrier 102. According to one embodiment, the tacky layer may include a tacky pad 104, although embodiments are not so limited and include within their scope a tacky layer including an adhesive layer, or any other layer promoting adhesion of and to the layer. The tacky pads may, for example, be placed onto the cavities by vacuum pick nozzle, other techniques and/or tools for handling the tacky pads being within the purview of embodiments. By “tacky pad,” what is meant in the context of embodiments is a mass of material that is adapted to adhere onto the carrier and to be mechanically removed therefrom, and further adapted to allow a microelectronic component, such as a die, for example, to adhere thereto. The material of the tacky pad may preferably be adapted to substantially avoid degradation at a temperature above 300 degrees Celsius. Additionally, preferably the material of the tacky pad may allow the tacky pad to be used multiple times with substantially no change to a tackiness thereof. For example, most preferably, the tacky pad may be made of silicone. The tacky pad may be adapted to prevent the die from shifting, to protect an active surface of the die from cracking, and to compensate the non-co planarity between the die and the IHS to ensure good bonding. Under an external pressure, the soft tacky pads may tend to flatten the ultra-thin die and thus advantageously force it to closely contact the IHS.

Referring still to FIGS. 1 and 2 by way of example, according to one embodiment, the carrier may be adapted to carry a plurality of microelectronic components, such as dies, thereon at respective locations 106. In the shown embodiment, the carrier 102 defines a plurality of cavities 108 corresponding to each of the respective locations 106, although embodiments are not so limited, and include within their scope any carrier configuration adapted to carry microelectronic components, such as dies, thereon. In such a case, a plurality of tacky pads 104 may be disposed at the respective locations 106 on the carrier, such as within each respective cavity 108.

Referring now to FIG. 3 by way of example, a method embodiment may include placing a die onto the tacky layer, such as placing dies 106 onto the tacky pads 104, such that an active surface 109 of each of the dies 106 adheres to a respective tacky pad 104. Placing the dies may include, for example, using a pick and place device, or any other technique as would be within the knowledge of the skilled person. According to one embodiment, the dies 106 may have a thickness below about 100 microns.

Referring next to FIG. 4 by way of example, a method embodiment may include bonding an IHS (integrated heat spreader) onto a backside of the die after placing the die onto the tacky layer, such as, for example, bonding a plurality of IHS's 110 onto respective backsides 112 of the plurality of dies 106 to form respective die-IHS combinations 114 therefrom. Preferably, a TIM (thermal interface material), such as a solder TIM, for example, is provided between each IHS 110 and its corresponding die 106. More preferably, a solder TIM is pre-deposited onto each IHS 110 prior to its mounting onto a corresponding one of the dies 106, and the carrier is sent through a reflow oven to reflow the TIM to bond the IHS's 110 onto the dies 16. The IHS′ 110 may be placed onto the respective dies 106 using a pick and place machine, or any other technique as would be within the knowledge of a skilled person,

Referring next to FIG. 5 by way of example, a method embodiment may include applying a load to backsides of each of the IHS's 110 after their placement onto the respective dies 106. For example, as shown in FIG. 5, a clip mechanism 116 may be clipped onto the carrier 102 as shown to apply a load onto backsides of all of the IHS's 110 simultaneously. The clip mechanism 116 may for example include individual clip portions 118 in order to flatten the dies 106 and to ensure good bonding between the dies and the IHS's 110. An embodiment may then include sending the carrier 102, including the clip mechanism 11 6 thereon, through a reflow oven.

Referring next to FIG. 6 by way of example, a method embodiment may include removing the die-IHS combination from the tacky layer, such as, for example, removing the die-IHS combinations 114 from the tacky pads 104. Removal may include, for example, using a pick nozzle 120, or any other technique as would be within the knowledge of a skilled person. FIG. 6 further shows solder bumps 122 on the removed die 106, the solder bumps 122 having emerged from tacky pad 104. Where a clip mechanism 116 is used, it may be removed prior to removal of each die-IHS combination. The tacky pads 104 may stay attached to the carrier 102 as a result of a stronger adhesion between them and the flat surface of the carrier than between them and the bumps 122, the adhesion being provided by the tackiness of the material of the tacky pads.

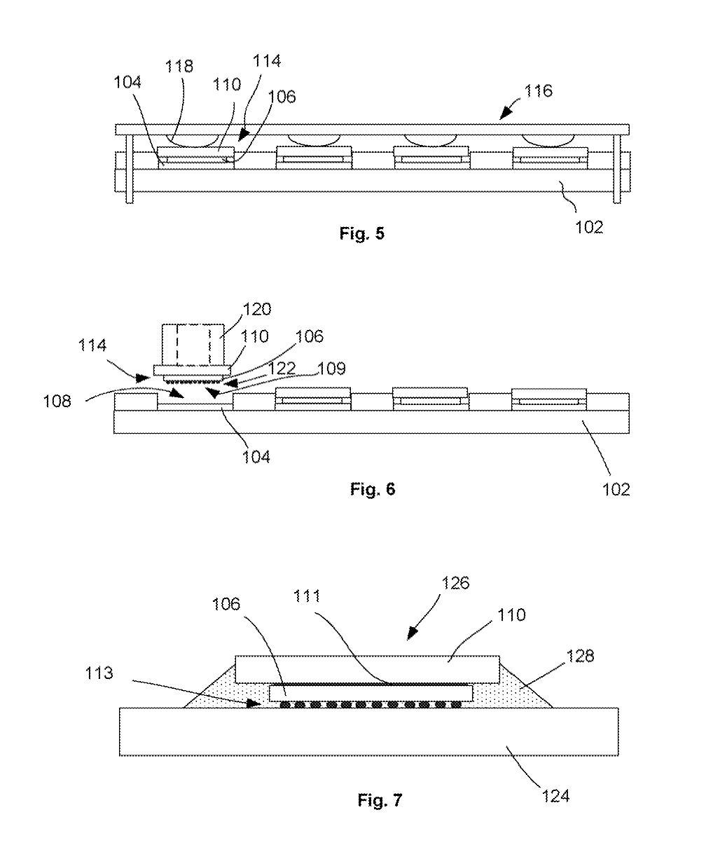

Referring next to FIG. 7 by way of example, a method embodiment may include mounting the die-IHS combination onto a package substrate, such as, for example, mounting each die-IHS combination 114 onto a respective package substrate 124 to yield microelectronic packages, such as package 126. Each die-IHS combination 114 may be configured, as shown in FIGS. 6 and 7, to be flip chip mounted onto the package substrate 124, other configurations of the die-IHS combination 114 to allow other mounting techniques onto the substrate 124 being within the purview of embodiments. The resulting package 126 may include the die 106, the IHS 110, the TIM 111, solder joints 113, package substrate 124, and underfill material 128 as shown.

Advantageously, embodiments provide a method of making a microelectronic package, such as one including an ultra-thin die, for high volume manufacturing. Method embodiments allow the attachment of an ultra-thin die to a chip scale IHS to allow the IHS to act as a stiffener or rigidizer for the die prior to its mounting onto a package substrate, in this way providing a manufacturable solution to the problem of handling and packaging ultra-thin dies.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof

What is claimed is:

1. A method of making a microelectronic package comprising:
providing a carrier;
providing a tacky layer on the carrier,
placing a die onto the tacky layer such that an active surface of the die adheres to the tacky layer:
bonding an IHS onto a backside of the die after placing to form a die-IHS combination;
removing the die-IHS combination from the tacky layer; and
mounting the die-IHS combination onto a package substrate to form the package.

2. The method of claim 1, wherein the tacky layer comprises a tacky pad, the tacky pad being adapted to be adhere onto the carrier and be mechanically removed therefrom.

3. The method of claim 2 wherein:
the carrier is adapted to carry a plurality of die-IHS combinations thereon at respective locations thereof:
providing a tacky layer comprises placing a plurality of tacky pads at the respective locations on the carrier:
placing a die comprises placing a plurality of dies onto respective ones of the tacky pads;
bonding an IHS comprises bonding a plurality of IHS's onto respective backsides of the plurality of dies to form respective die-IHS combinations;
removing the die-IHS combination comprises removing each of the respective die-IHS combinations from respective ones of the tacky pads; and
mounting the die-IHS combination comprises mounting each of the respective die-IHS combinations onto a respective package substrate to yield respective packages therefrom.

4. The method of claim 3 wherein the carrier defines a plurality of cavities corresponding to the respective locations, each of the cavities being adapted to hold one of the tacky pads and one of the die-IHS combinations therein.

5. The method of claim 3, wherein the plurality of tacky pads comprise a material adapted to substantially avoid degradation at a temperature above 300 degrees Celsius.

6. The method of claim 5 wherein the plurality of tacky pads comprise a material that allows the tacky pads to be used multiple times with substantially no change to a tackiness thereof.

7. The method of claim 6, wherein the plurality of tacky pads comprise silicone.

8. The method of claim 3 wherein placing a die includes placing each of the plurality of dies onto the respective ones of the tacky pads after placing the plurality of tacky pads at the respective locations on the carrier.

9. The method of claim 3, wherein bonding a plurality of IHS's comprises
placing a solder TIM between each of the plurality of IHS's and a corresponding one of the plurality of dies; and
sending the carrier through a reflow oven to reflow the TIM to bond the plurality of IHS's to corresponding ones of the plurality of dies.

10. The method of claim 9, wherein bonding a plurality of IHS's comprises placing a load mechanism onto backsides of the IHS's to apply a load onto respective ones of the IHS's.

11. The method of claim 10, wherein the load mechanism comprises a clip mechanism adapted to clip onto the carrier to apply a load onto backsides of all of the IHS's simultaneously.

12. The method of claim 1, wherein the die has a thickness less than or equal to about 100 microns.

13. The method of claim 3, wherein removing each of the respective die-IHS combinations includes using a pick nozzle.
